(19) United States
(12) Patent Application Publication
(10) Pub. No.: US 2007/0200165 A1
(43) Pub. Date: Aug. 30, 2007

(54) Floating gate, a nonvolatile memory device including the floating gate and method of fabricating the same

(76) Inventors: Young-Cheon Jeong, Yongin-si (KR); Chul-Soon Kwon, Seoul (KR); Jae-Min Yu, Anyang-si (KR); Jae-Hyun Park, Yongin-si (KR); Jung-Ho Moon, Seoul (KR); Soung-Youb Ha, Gunpo-si (KR); Byeong-Cheol Lim, Pusan (KR)

Correspondence Address: HARNESS, DICKEY & PIERCE, P.L.C., P.O. BOX 8910, RESTON, VA, 20195, US

(21) Appl. No.: 11/656,454

(22) Filed: Jan. 23, 2007

(30) Foreign Application Priority Data
Jan. 23, 2006 (KR) 10-2006-0006879

(51) Int. Cl. H01L 29/788

(52) U.S. Cl. 257/315; 257/E29.129

(57) ABSTRACT

Example embodiments may provide a nonvolatile memory device. The example embodiment nonvolatile memory device may include a floating gate structure formed on a semiconductor substrate with a gate insulating layer between them and/or a control gate formed adjacent to the floating gate with a tunneling insulation layer between them. The floating gate may include a first floating gate formed on the gate insulating layer, a second floating gate formed on the first floating gate with a first insulating pattern between them, and/or a gate connecting layer formed on at least one sidewall of the first insulating pattern so that the gate conducting layer may electrically connect the first floating gate and the second floating gate. The second floating gate may have a tip formed at its longitudinal end that may not contact the gate connecting layer.

### PRIORITY STATEMENT

This U.S. non-provisional patent application claims priority under 35 U.S.C. § 119 of Korean Patent Application No. 2006-0006879 filed on Jan. 23, 2006, the entire contents of which are hereby incorporated by reference.

### BACKGROUND

Example embodiments relate to a semiconductor device, for example, to a nonvolatile memory device and method of forming the same.

Memory devices may be classified into volatile memory devices and nonvolatile memory devices. Volatile memory devices, such as DRAMs or SRAMs, may have a rapid data input and output speed, but they may lose data when cut off from their power supply. On the contrary, nonvolatile memory devices may retain stored data when cut off from their power supply.

A flash memory device, which is a nonvolatile memory device, may be a highly integrated device that may combine the advantage of an erasable programmable read only memory (EPROM) with the advantage of an electrically erasable programmable read only memory. Flash memory devices may be classified into floating gate type flash memory devices and floating trap type flash memory devices, depending on the type of data storage layer constituting a unit cell. Flash memory devices may be further classified into stacked gate type flash memory devices and split gate type flash memory devices, depending on the structure of a unit cell.

FIG. 1 is a sectional view of a related art stacked gate type memory device. As shown in FIG. 1, in a related art stacked gate cell, a floating gate 30, and/or a control gate 40 may be sequentially stacked on a substrate 10. A tunnel oxide layer 20 may be between the substrate 10 and the floating gate 30, and a blocking oxide layer 25 may be between the floating gate 30 and the control gate 40. Source and drain regions 51 and 53 may be positioned at both sides of the stack gate structure in the substrate 10. In the above stacked gate cell, a programming operation may be performed in the drain region 53 using a channel hot electron injection (CHEI), and an erase operation may be performed in the source region 51 using Fowler-Nordheim (F-N) tunneling.

The related art stacked gate cell may have a smaller size and/or higher integration; however, it may also suffer from over-erase. Over-erase may occur when a floating gate is over-discharged during an erase operation in the stack gate cell. The threshold voltage of the over-discharged cell shows a negative value. Thus, current may flow in an undesired direction or at an undesired time.

To solve the over-erase problem, two types of cell structure have been introduced: 1) two-transistor cells and 2) split gate cells.

FIG. 2 is a sectional view of a related art memory device having a two-transistor cell. As shown in FIG. 2, a two-transistor cell may include a select transistor spaced apart from a conventional stack gate cell. The select transistor may include a select gate 40s on a gate insulating layer 20b on a substrate 10 and source and drain regions on both sides of the select gate 40s in the substrate 10. The conventional stack gate cell may perform program and erase operations. In the related art memory device of FIG. 2, when a cell is not selected, the select gate 40s may reduce or prevent a leakage current from the over-discharged floating gate 30. The related art's two-transistor cell structure may have difficulty in achieving the high integration required of a memory device because it may have an impurity diffusion region 53 between the stack gate cell and the select transistor.

FIG. 3 is a sectional view of a related art split gate type memory device. The split gate type memory cell may allow a directional F-N tunneling current so as to reduce or prevent over-erase and/or enhance the erase efficiency.

As shown in FIG. 3, in a related art split gate type cell, a floating gate 30 and a control gate 40 may be positioned on a channel region 55 between a source region 51 and a drain region 53, while a gate insulating layer 20 may be between the floating gate 30 and the channel region 55. Because the control gate 40 may be positioned on the channel region 55, a leakage current from the floating gate 30 over-discharging may be reduced or prevented. Also, the floating gate 30 may have tips 30p at both upper edges formed using a local oxidation of silicon (LOCOS) technology. The tips 30p may be formed by forming a bird's beak using a partial oxidation of silicon at both ends of a silicon oxide layer.

Electrons stored in the floating gate 30 in an erase operation of the related art memory device may be removed while flowing through a channel of the tip 30p, the tunneling insulation layer 25, and/or the control gate 40. An F-N tunneling current may flow in an opposite direction to the flow of the electrons. The F-N tunneling current may have a directionality and enhance the erase efficiency because of the tips 30p that may be formed at both edges of the floating gate.

Because the related art method may use the LOCOS technique to form the tips by forming birds' beaks, it may not achieve a required level of integration. Because a bird's beak formed at an end of the silicon oxide may have an irregular shape, the tips may be formed irregularly, and/or the erase characteristic may be irregular so that the reliability of the memory device may deteriorate.

### SUMMARY

Example embodiments may provide an integrated nonvolatile memory device with improved reliability and a method of fabricating the same.

Example embodiments may provide a nonvolatile memory device including: a floating gate on a semiconductor substrate with a gate insulating layer between them and/or a control gate adjacent to the floating gate with a tunneling insulation layer between them. The floating gate may include a first floating gate on the gate insulating layer, a second floating gate on the first floating gate with a first insulating pattern between them, and/or a gate connecting layer on at least one sidewall of the first insulating pattern that electrically connects the first floating gate and the second floating gate. The second floating gate may have a tip formed at a longitudinal end of the second floating gate which may not contact the gate connecting layer.

In an example embodiment, the first floating gate, the second floating gate, and/or the gate connecting layer may be formed of the same material.

An example embodiment nonvolatile memory device may include a second insulating pattern on the second floating gate. The first insulating pattern may be formed of silicon oxide or the like and the second insulating pattern may be formed of silicon nitride or the like.

In an example embodiment, a control gate may be positioned on a gate insulating layer at one side of a floating gate, a source line may be positioned in the semiconductor substrate at the other side of the floating gate, and a drain region may be positioned in the semiconductor substrate opposite to the floating gate, and the control gate may be positioned between the drain region and the floating gate.

In an example embodiment, a control gate may be positioned on a floating gate, a second floating gate may have an opening that exposes a first insulating pattern, and a tip may be formed at a longitudinal end of the opening. The control gate may have a lower portion inserted into the opening, in contact with the first insulating pattern. Also, a gate insulating layer may be formed on four sidewalls of the first insulating pattern.

An example embodiment method of forming a nonvolatile memory device may include forming a gate insulating layer on a semiconductor substrate, forming a floating gate structure on the gate insulating layer, forming a tip at a longitudinal end of the second conductive pattern, and/or forming a control gate at a position adjacent to the tip. The floating structure may include a first conductive pattern, a first insulating layer, and/or a second conductive pattern sequentially stacked on the gate insulating layer. The second conductive pattern may extend downward from at least one sidewall thereof and may be electrically connected to the first conductive pattern.

An example embodiment method may further include forming a second insulating pattern on the second conductive pattern. The tip may be formed at the longitudinal end of the second conductive pattern exposed between the first insulating pattern and the second insulating pattern.

In an example embodiment, a floating gate structure may be formed by a variety of methods. For example, the floating gate structure may be formed by forming and patterning a first conductive layer and/or a first insulating layer on the gate insulating layer to form a first preliminary conductive pattern and/or a first preliminary insulating pattern, forming a second conductive layer and/or a second insulating layer on the semiconductor substrate, and/or patterning the second insulating layer, the second conductive layer, the first preliminary insulating pattern, and/or the first preliminary conductive pattern to form the second insulating pattern, the second conductive pattern, the first insulating pattern, and/or the first conductive pattern. The first insulating pattern and the first conductive pattern may be formed by removing a middle portion of each of the first preliminary insulating pattern and the first preliminary conductive pattern to divide each of the first preliminary insulating pattern and the first preliminary conductive pattern into two portions. The second conductive pattern may have a longitudinal end exposed between the first insulating pattern and the second insulating pattern on at least one sidewall of the second conductive pattern.

The first insulating layer may be formed of silicon oxide or the like and the second insulating layer may be formed of silicon nitride or the like.

The tip may be formed by performing a thermal oxidation process or the like on the longitudinal end of the second conductive pattern.

The example embodiment method of forming a floating gate structure may further include forming a tunneling insulation layer on the semiconductor substrate.

An example method of forming a floating gate structure may include forming and patterning a first conductive layer and/or a first insulating layer on a gate insulating layer to form a first conductive pattern and/or a first insulating pattern, forming a second conductive layer and/or a second insulating layer on a semiconductor substrate, patterning the second insulating layer and/or the second conductive layer to form a second preliminary insulating pattern and/or a second preliminary conductive pattern covering the first conductive pattern and/or the first insulating pattern; and/or patterning the second preliminary insulating pattern and/or the second preliminary conductive pattern to form the second insulating pattern and/or the second conductive pattern partially exposing the upper surface of the first insulating pattern. A sidewall of the second conductive pattern may be exposed between the first insulating pattern and the second insulating pattern.

The first insulating layer may be formed of silicon oxide or the like and the second insulating layer may be formed of silicon nitride or the like.

The tip may be formed by performing a thermal oxidation process of the sidewall of the second conductive pattern exposed between the first insulating pattern and the second insulating pattern.

An example embodiment method of forming a floating gate structure may further include forming a tunneling insulation layer between the tip and the control gate prior to forming the control gate.

The tunneling insulation layer may be formed by thermally oxidizing the second conductive pattern while the tip is formed.

### BRIEF DESCRIPTION OF THE FIGURES

Example embodiments are described in the following figures, wherein like reference numerals refer to like parts throughout the various figures unless otherwise specified. In the figures:

FIG. 1 is a sectional view of a related art stacked gate type memory device;

FIG. 2 is a sectional view of a related art memory device having two-transistor cell;

FIG. 3 is a sectional view of a related art split gate type memory device;

FIG. 4 is a plan view of an example embodiment nonvolatile memory device;

FIGS. 5A and 5B are sectional views taken along lines A-A′ and B-B′ of the example embodiment device in FIG. 4;

FIG. 6 is a plan view of an example embodiment nonvolatile memory device;

FIGS. 7A and 7B are sectional views taken along lines A-A′ and B-B′ of the example embodiment device in FIG. 6;

FIG. 8 is a plan view of an example embodiment nonvolatile memory device;

FIGS. 9A and 9B are sectional views taken along lines A-A′ and B-B′ of the example embodiment device in FIG. 8;

FIGS. 10A through 17A and FIGS. 10B through 17B are sectional views taken along lines A-A′ and B-B′ of the example embodiment device in FIG. 4, showing an example embodiment method of forming a nonvolatile memory device;

FIGS. 18A through 24A and FIGS. 18B through 24B are sectional views taken along lines A-A′ and B-B′ of the example embodiment device in FIG. 6, showing an example embodiment method of forming a nonvolatile memory device; and

FIGS. 25A through 30A and FIGS. 25B through 30B are sectional views taken along lines A-A′ and B-B′ of the example embodiment device in FIG. 8, showing an example embodiment method of forming a nonvolatile memory device.

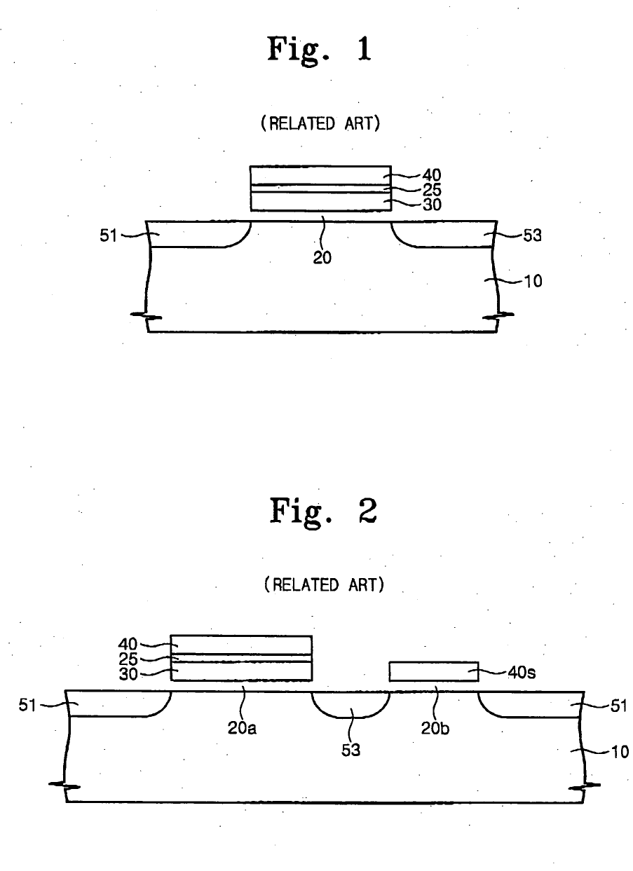

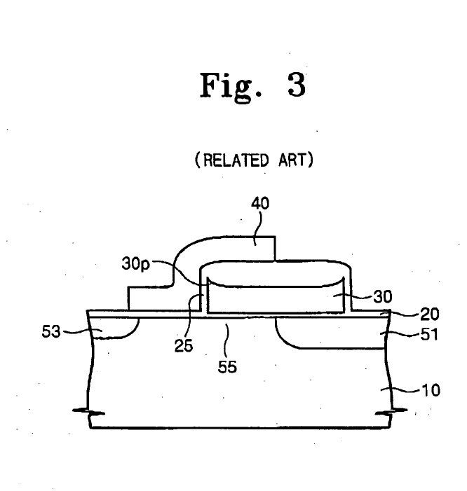

### DETAILED DESCRIPTION

Detailed example embodiments are disclosed herein. However, specific structural and/or functional details disclosed herein are merely representative for purposes of describing example embodiments. The claims may, however, may be embodied in many alternate forms and should not be construed as limited to only example embodiments set forth herein.

It will be understood that when a component is referred to as being “on,” “connected to” or “coupled to” another component, it can be directly on, connected to or coupled to the other component or intervening components may be present. In contrast, when a component is referred to as being “directly on,” “directly connected to” or “directly coupled to” another component, there are no intervening components present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one component or feature's relationship to another component(s) or feature(s) as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, and/or components.

Unless otherwise defined, all terms (including technical and/or scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Reference will now be made to example embodiments, which are illustrated in the accompanying drawings, wherein like reference numerals refer to the like components throughout. Example embodiments should not be construed as limited to the particular shapes of regions illustrated in these figures but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the claims.

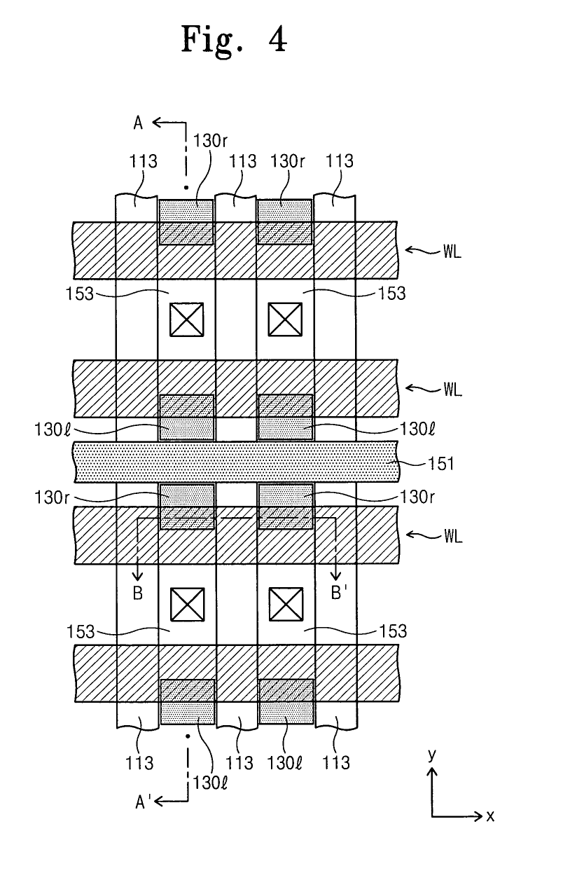

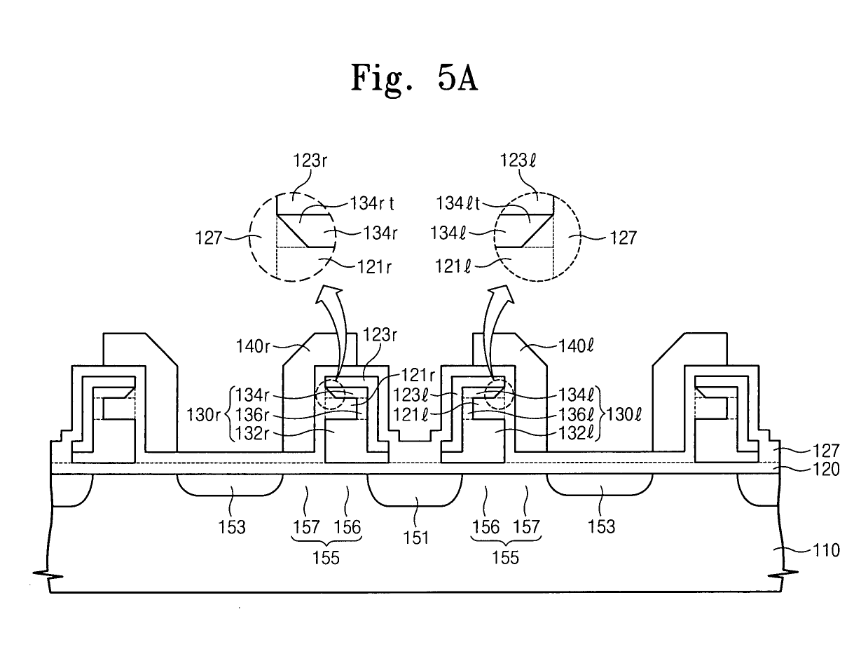

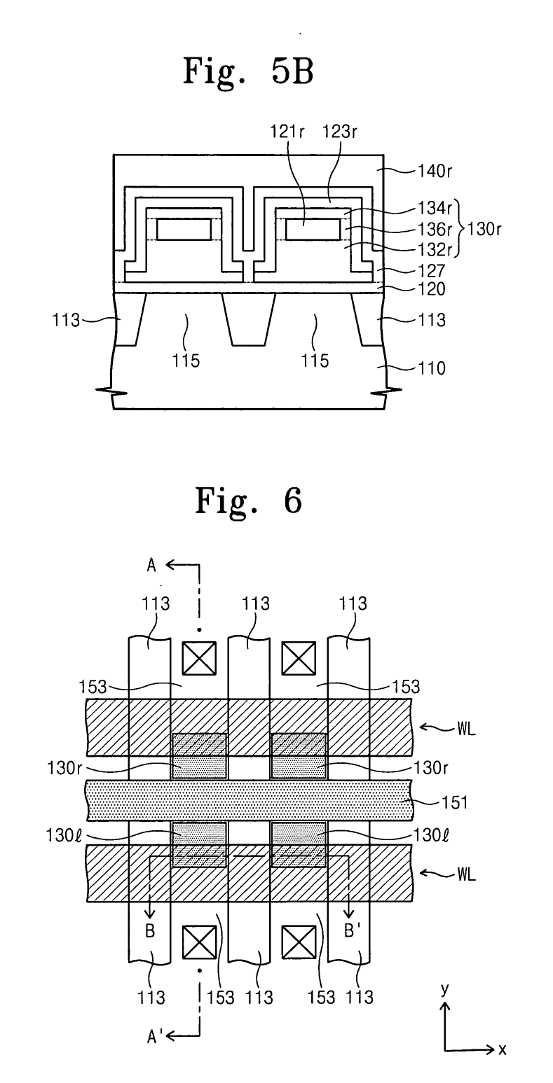

FIG. 4 is a plan view of an example embodiment nonvolatile memory device, and FIGS. 5A and 5B are sectional views taken along lines A-A′ and B-B′ of the example embodiment device in FIG. 4.

As shown in FIGS. 4, 5A, and 5B, an active region 115 may be defined by a device isolation layer 113 formed in a semiconductor substrate 110. Floating gates 130l and 130r may be placed on the active regions 115 with a gate insulating layer 120 between the semiconductor substrate 110 and the floating gates 130l and 130r. The floating gates 130l and 130r may be arranged in first and second directions, for example, in an x-axis direction and a y-axis direction, in a matrix configuration. The floating gates 130l and 130r arranged in the first direction may share a word line (WL), and two floating gates 130l and 130r arranged in the second direction may share a drain region 153 or a source region 151. The floating gates 130l and 130r may include lower first floating gates 132l, 132r, upper second floating gates 134l, 134r, and/or gate connecting layers 136l and 136r. The first floating gates 132l and 132r and the second floating gates 134l and 134r may be separated by first insulating patterns 121l and 121r and may be electrically connected by the gate connecting layers 136l and 136r on the first insulating patterns 121l and 121r. The gate connecting layers 136l and 136r may cover at least one and up to three sidewalls of the first insulating patterns 121l and 121r. Second insulating patterns 123l and 123r may cover upper surfaces of the second floating gates 134l and 134r. The second insulating patterns 123l and 123r may extend downward from the sidewalls of a tunneling insulation layer 127 to cover the sidewalls of the second floating gates 134l and 134r, the gate connecting layers 136l and 136r, and/or the first floating gates 132l and 132r. The first insulating patterns 121l and 121r and the second insulating patterns 123l and 123r may be made of materials having different properties. For example, the first insulating patterns 121l and 121r may be made of silicon oxide or the like and the second insulating patterns 123l and 123r may be made of silicon nitride or the like. Tips 134lt and 134rt may be easily formed at regions where the second floating gates 134l and 134r between the first insulating patterns 121l and 121r and the second insulating patterns 123l and 123r contact the tunneling insulation layer 127. The tunneling insulation layer 127 may cover the substrate on which the floating gates 130l and 130r are formed.

Control gates 140l and 140r may be formed at one side of the floating gates 130l and 130r on the active regions 115, potentially forming a split gate type memory cell. The control gates 140l and 140r of each memory cell may be together extend in the first direction and constitute the word line WL.

A source line 151 extending in the first direction may be on the active region between the device isolation layers 113, which may be arranged in the second direction. Drain regions 153 may be in the active region facing the source line 151 with the floating gates 130l and 130r between them. A channel region 155 between the source line 151 and the drain region 153 may include a first channel region 156 positioned under a floating gate and a second channel region 157 positioned under a control gate. Unlike in the stacked gate cell, because the second channel region 157 may be positioned under the control gates 140l and 140r in an example embodiment split gate cell, the second channel region 157 may reduce or prevent a leakage current from being generated in the first channel region 156 positioned under the over-discharged floating gates 130l and 130r if the control gates 140l and 140r are turned off.

Because the second floating gates 134l and 134r have tips 134lt and 134rt where the gates contact the tunneling insulation layer 127, electrons stored in the floating gates 130l and 130r flow from the tips 134lt and 134rt of the second floating gates 134l and 134r to the control gates 140l and 140r in an erase operation and F-N tunneling current flows in an opposite direction to the flow direction of the electrons. Because the F-N tunneling current may have a directionality due to the tips 134lt and 134rt formed at edges of the second floating gates, erase efficiency may be increased. Example embodiment nonvolatile memory devices may have higher integration than a related art nonvolatile memory device having tips formed using the LOCOS technique.

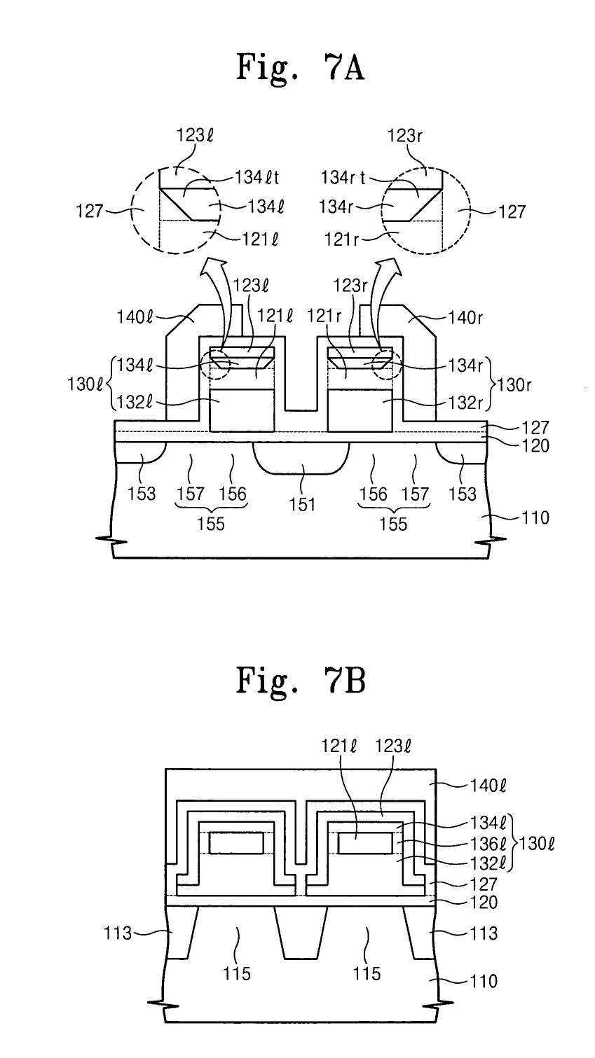

FIG. 6 is a plan view of an example embodiment nonvolatile memory device, and FIGS. 7A and 7B are sectional views taken along lines A-A′ and B-B′ of FIG. 6. The example embodiment shown in FIGS. 6-7 will be described except for similar parts already described in the example embodiment memory cell in FIGS. 4-5.

As shown in FIGS. 6, 7A and 7B, gate connecting layers 136l and 136r may cover both sidewalls of first insulating patterns 121l and 121r. Second insulating patterns 123l and 123r may cover both sidewalls of second floating gates 134l and 134r, first insulating patterns 121l and 121r, and/or first floating gates 132l and 132r. The second floating gates 134l and 134r may have tips 134lt and 134rt not covered by the second insulating patterns 123l and 123r.

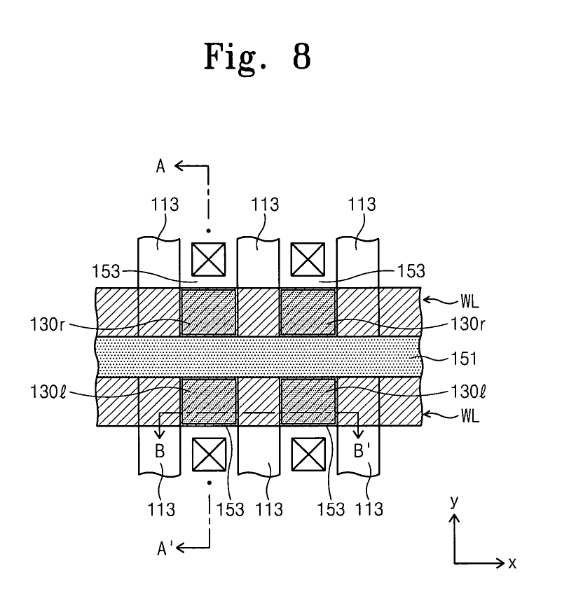

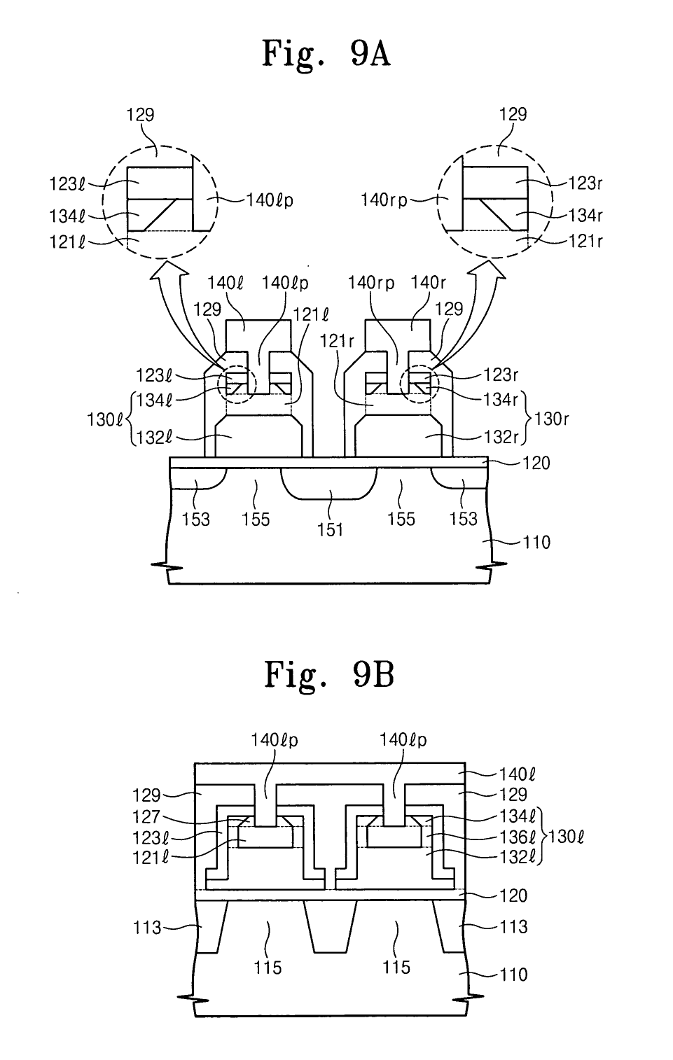

FIG. 8 is a plan view of an example embodiment nonvolatile memory device, and FIGS. 9A and 9B are sectional views taken along lines A-A′ and B-B′ of FIG. 8. The example embodiment in FIGS. 8-9 may provide a stack gate type memory cell in addition to those features of other example embodiments previously described.

As shown in FIGS. 8, 9A and 9B, first floating gates 132l and 132r may be on active regions 115 of a semiconductor substrate 110 with a gate insulating layer 120 between them, and second floating gates 134l and 134r may be on the first floating gates 132l and 132r with first insulating patterns 121l and 121r between them. The first floating gates 132l and 132r may be electrically connected to the second floating gates 134l and 134r by gate connecting layer 136l and 136r, which may cover two parallel sidewalls of the first insulating patterns 121l and 121r. The gate connecting layers 136l and 136r may cover up to two sidewalls that face a first direction and are parallel in a second direction of the first insulating patterns 121l and 121r. The gate connecting layers 136l and 136r may cover up to two sidewalls that face the second direction and are parallel in the first direction of the first insulating patterns 121l and 121r, thus electrically connecting the first floating gates 132l and 132r with the second floating gates 134l and 134r. The gate connecting layers 136l and 136r may cover all of four sidewalls of first insulating patterns 121l and 121r. The structure, shape, and other characteristics of the gate connecting layers 136l and 136r may be properly selected and matched to increase integration, erase efficiency, and the like of the example embodiment nonvolatile memory device. For example, if the first insulating patterns cover four sidewalls of the first insulating patterns, integration may be decreased but erase efficiency may be increased. If the first insulating patterns cover two sidewalls of the first insulating patterns, erase efficiency may be reduced, but integration may increase.

Second insulating patterns 123l and 123r may be positioned on the second floating gates 134l and 134r. The second insulating patterns 123l and 123r may extend downward from two parallel sidewalls to cover the second floating gates 134l and 134r, the first insulating patterns 121l and 121r, and/or the first floating gates 132l and 132r. The second insulating patterns 123l and 123r may cover at least the upper surfaces of the second floating gates 134l and 134r. The first insulating patterns 121l and 121r and the second insulating patterns 123l and 123r may include materials having different properties. For example, the first insulating patterns 121l and 121r may be made of silicon oxide or the like and the second insulating patterns 123l and 123r may be made of silicon nitride or the like.

Control gates 140l and 140r may be positioned on the first insulating patterns 121l and 121r. The control gates may have conductive plugs 140lp and 140rp penetrating the second insulating patterns 123l and 123r and an oxide layer 129. A tunneling insulation layer on the first insulating patterns 121l and 121r may be between the second floating gates 134l and 134r and the conductive plugs 140lp and 140rp while surrounding the conductive plugs 140lp and 140rp. The memory cell of the example embodiment nonvolatile memory device may be the stack gate type. Because the tips 140lt and 140rt formed in the second floating gates may be directed toward conductive plugs 140lp and 140rp, the F-N tunneling current may have the directionality in the erase operation, increasing the erase efficiency.

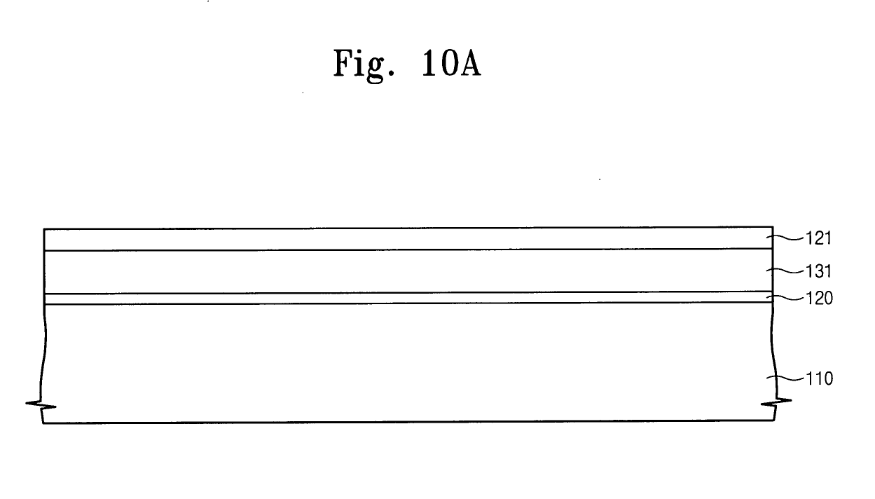

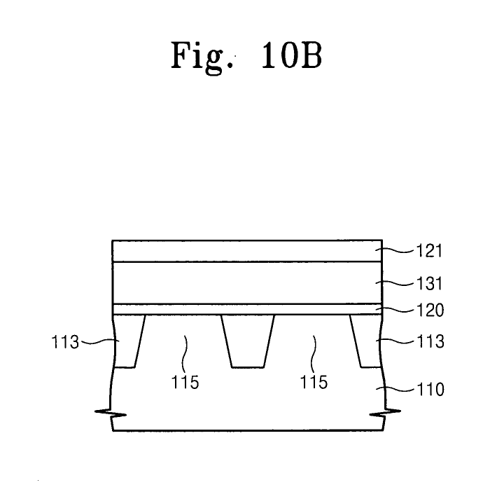

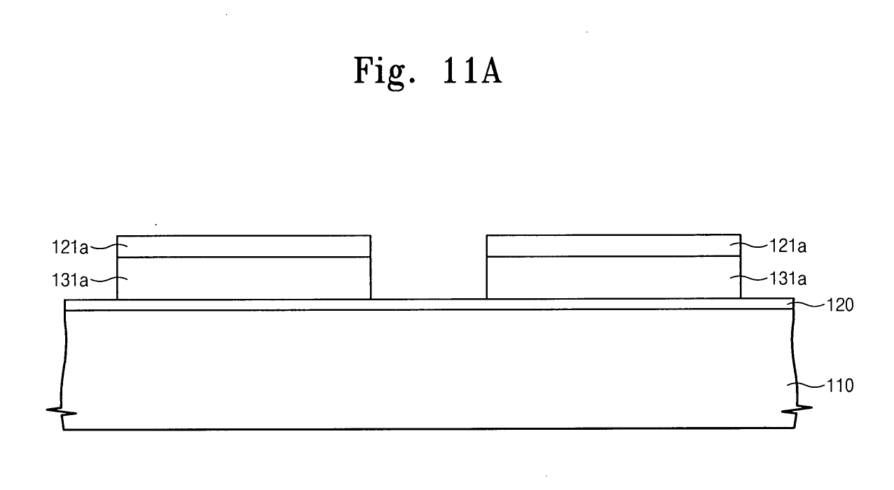

An example embodiment may provide a method of fabricating a nonvolatile memory. FIGS. 10A through 17A and FIGS. 10B through 17B are sectional views taken along lines A-A′ and B-B′ of the example embodiment memory device in FIG. 4. FIGS. 10A through 17A and FIGS. 10B through 17B illustrate an example embodiment method of forming a nonvolatile memory device.

As shown in FIGS. 4, 10A and 10B, a device isolation layer 115 may define an active region 115 in a semiconductor substrate 110. The semiconductor substrate 110 may be a single crystalline bulk silicon substrate or a substrate including an epitaxial layer, a buried oxide layer, and/or a doped region to enhance characteristics of a semiconductor device and provide a desired structure, for example, a silicon oxide insulator (SOI) substrate or the like. The semiconductor substrate 110 may be a p-type semiconductor substrate doped with p-type impurities, for example, boron (B) or the like. The device isolation layer 113 may be formed of silicon oxide by any device isolation process, for example, a shallow trench isolation process or the like, known to those skilled in the art.

A gate insulating layer 120, a first conductive layer 131, and/or a first insulation layer 121 may be formed on the semiconductor substrate 110. The gate insulating layer 120 may be formed of silicon oxide by any thin film forming process or the like. The first conductive layer 131 may be formed of doped polysilicon by any thin film forming process or the like. The first insulation layer 121 may be formed of silicon oxide by any thin film forming process or the like.

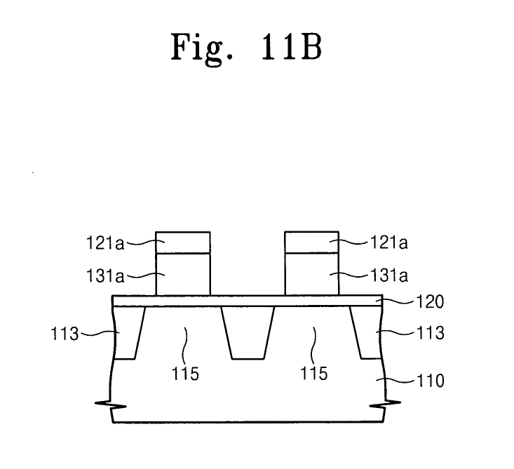

As shown in FIGS. 4, 11A, and 11B, a first preliminary insulation pattern 121a and a first preliminary conductive pattern 131a may be formed by a photolithography, etching, and/or other suitable process. The first preliminary insulation pattern 121a and the first preliminary conductive pattern 131a may be arranged in a matrix configuration on the active region 115 of the semiconductor substrate 110.

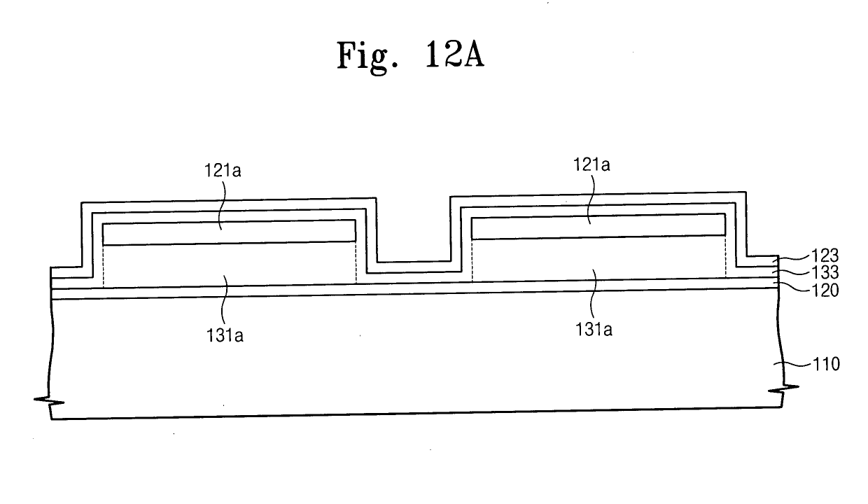

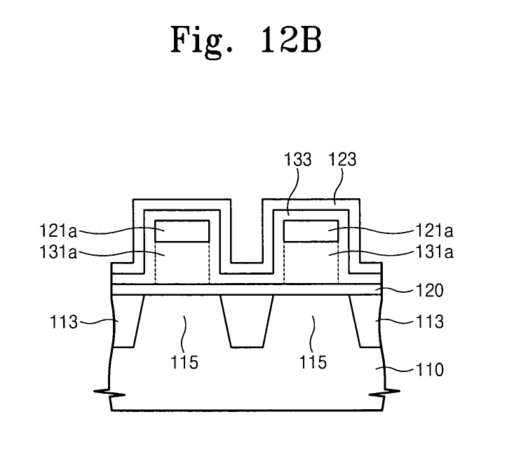

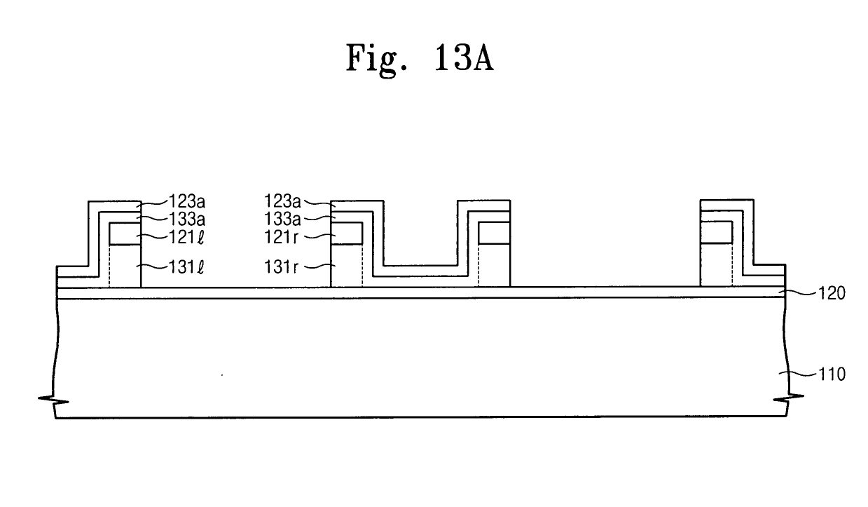

As shown in FIGS. 4, 12A, and 12B, a second conductive layer 133 and a second insulation layer 123 may cover an upper surface of the semiconductor substrate 110. The second conductive layer 133 may be formed of doped polysilicon or the like by, for example, a thin film forming process, and the second insulation layer 123 may be formed of silicon nitride or the like by, for example, a thin film forming process. An atomic layer deposition (ALD) technique or the like may be used to form the second conductive layer 133 and the second insulation layer 123 on a surface of the first preliminary conductive pattern 131a and the first preliminary insulation pattern 121a. The second conductive layer 133 may cover an upper surface and up to four sidewalls of the first preliminary insulation pattern 121a. The first preliminary insulation pattern 121a may be isolated between the first preliminary conductive pattern 131a and the second conductive layer 133.

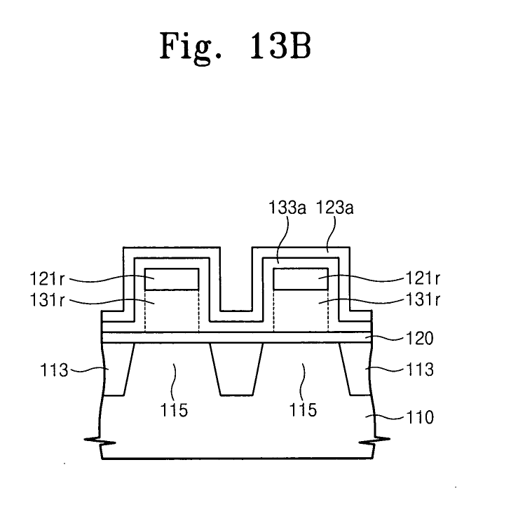

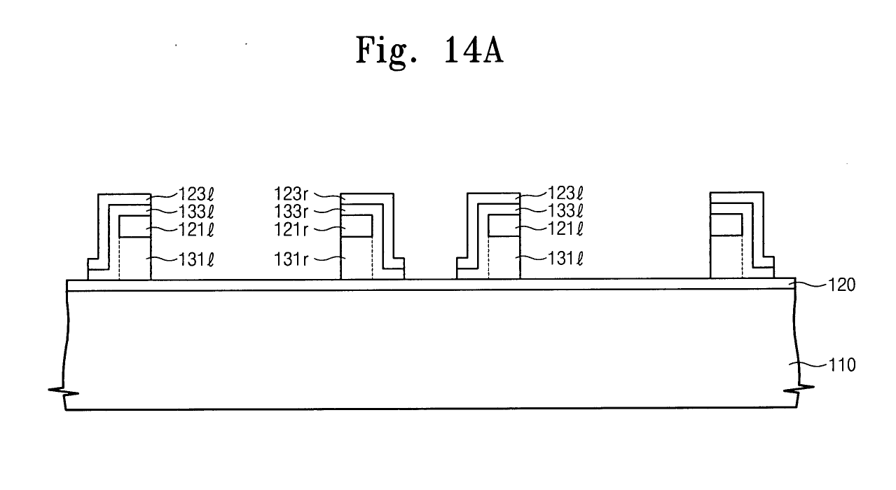

As shown in FIGS. 4, 13A and 13B, a photolithography, etch, and/or another suitable process may be performed to form first conductive patterns 131l and 131r and first insulating patterns 121l and 121r. The first two conductive patterns 131l and 131r and the first two insulation patterns 121l and 121r may be formed by removing a middle portion of each of the first preliminary conductive pattern 131a and the first preliminary insulation pattern 121a. The first two conductive patterns 131l and 131r and the first two insulation patterns 121l and 121r may be self-aligned under a second preliminary conductive pattern 133a and a second preliminary insulation pattern 123a extending in a first direction.

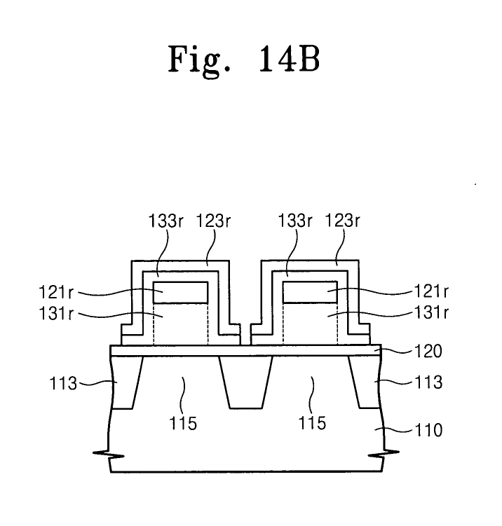

As shown in FIGS. 4, 14A and 14B, a photolithography, etching, and/or other suitable process may be performed to form second conductive patterns 133l and 133r and second insulating patterns 123l and 123r. The first conductive patterns 131l and 131r may be electrically connected with the second conductive patterns 133l and 133r. The second conductive patterns 133l and 133r and the second insulating patterns 123l and 123r may extend in the first direction and second direction, respectively.

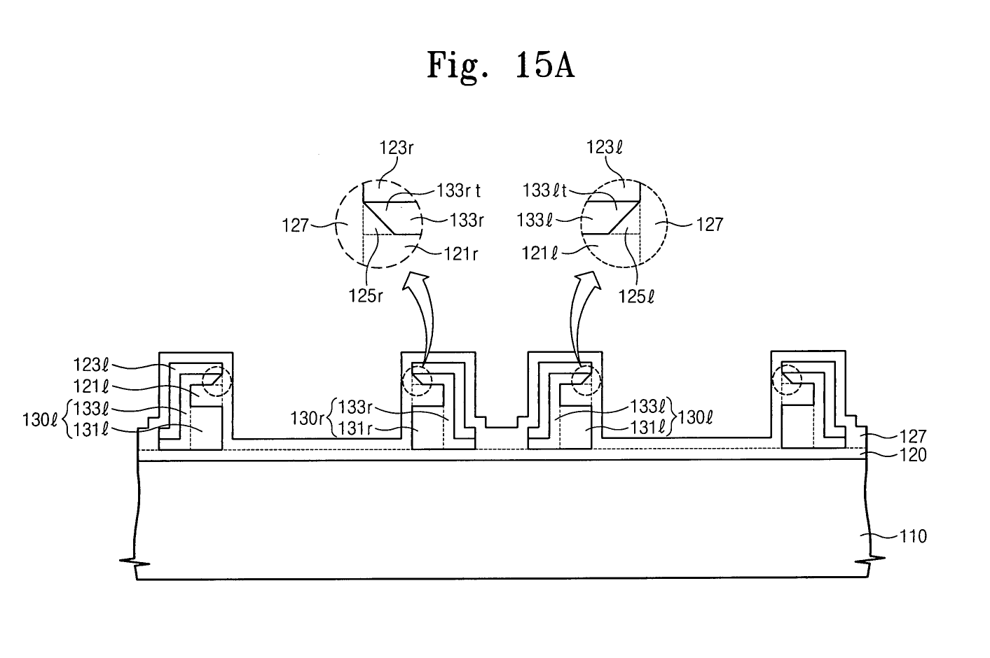

As shown in FIGS. 4, 15A, and 15B, a thermal oxidation process may be performed to form tips 133lt and 133rt at one end of the second conductive patterns 133l and 133r. As shown in circles of FIG. 15A, the tips 133lt and 133rt may be formed while the second conductive patterns 133l and 133r are partially transformed into oxide layers 125l and 125r by a thermal oxidation process. If the first insulating patterns 121l and 121r are silicon oxide and the second insulating patterns 123l and 123r are silicon nitride, the thermal oxidation process may oxidize the polysilicon adjacent to the silicon oxide faster than it oxidizes the polysilicon adjacent to the silicon nitride. The tips 133lt and 133rt may be easily formed by this method. If the tips are formed by a related art LOCOS process, the tips may be irregularly formed and may break easily. In the related art, the erase characteristic of the nonvolatile memory device may become irregular and decrease device reliability. Because birds' beaks may be formed in order to form the tips in the related art, integration may be limited for a high density nonvolatile memory device. In an example embodiment, because it may not be necessary to form the birds' beaks to form the tips, a highly integrated nonvolatile memory device may be fabricated more reliably.

The first conductive patterns 131l and 131r and the second conductive patterns 133l and 133r that form tips may constitute floating gates 130l and 130r. The floating gates 130l and 130r may be arranged in the first direction and the second direction, respectively.

A tunneling insulation layer 127 may be formed on an entire upper surface of the resultant semiconductor substrate 110. The tunneling insulation layer may be formed of silicon oxide by a thin film forming process or the like.

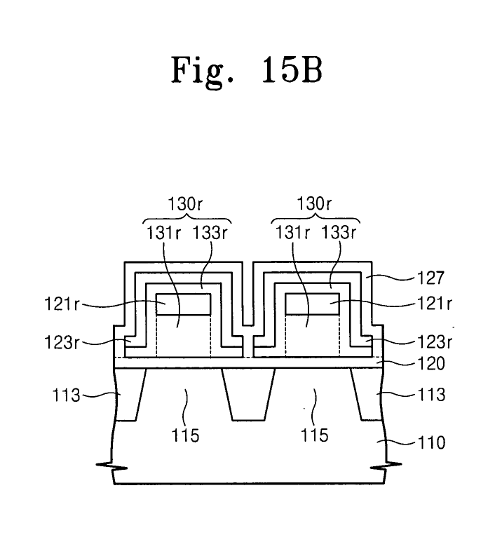

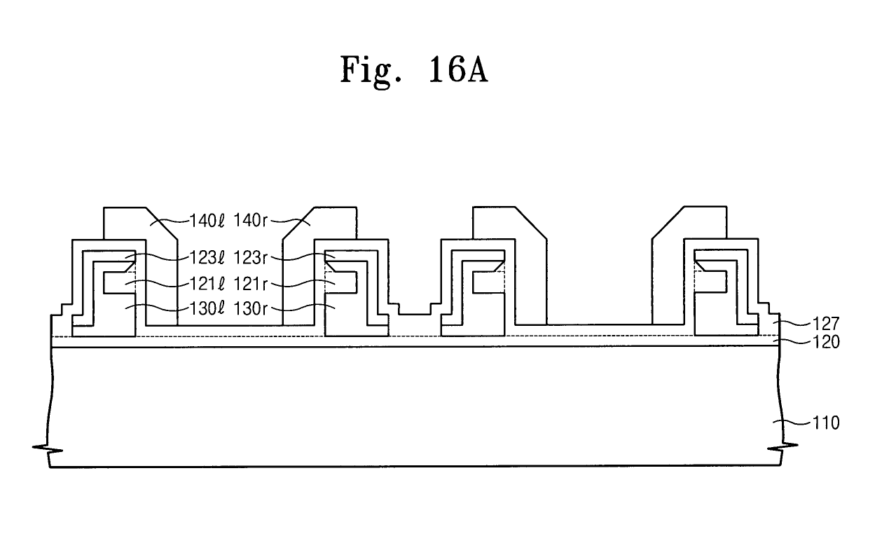

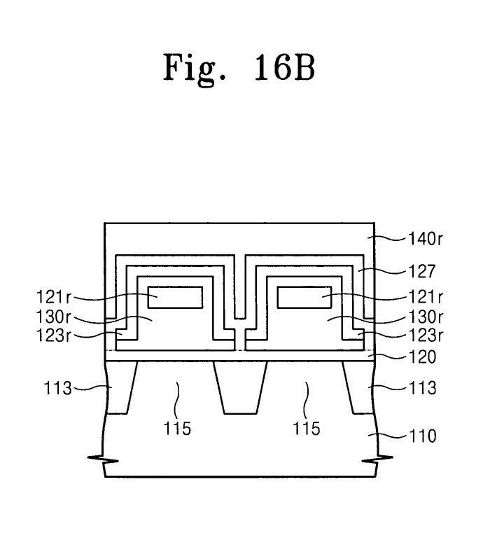

As shown in FIGS. 4, 16A, and 16B, a conductive layer may be formed on an upper surface of the resultant semiconductor substrate 110 and may be subject to a photolithography and etching process to form third conductive patterns 140l and 140r extending in the first direction. The third conductive patterns 140l and 140r may be formed of doped polysilicon or in a stacked structure of a doped polysilicon layer and/or a silicide layer. The third conductive patterns 140l and 140r may serve as become control gates.

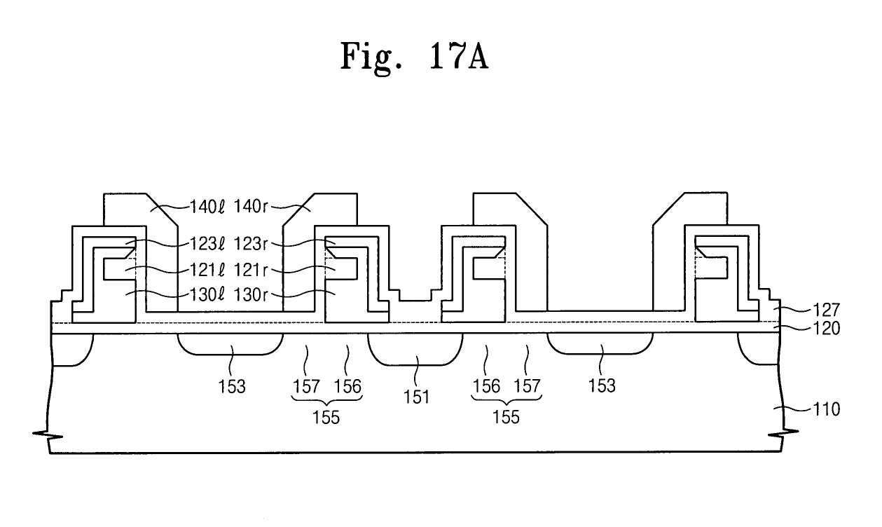

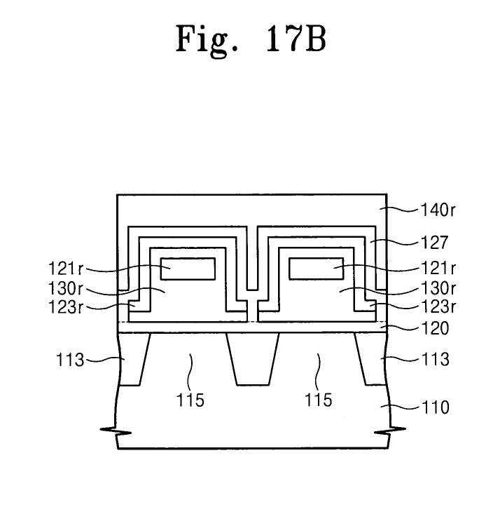

As shown in FIGS. 4, 17A, and 17B, an ion implantation process may be performed to form a source line 151 extending in the first direction in the active region 115 between the floating gates 130r and 130l and to form a drain region 153 in the active region 115 between the control gates 140l and 140r. A channel region 155 may be defined between the source line 151 and the drain region 153 from the ion implantation process. The channel region 155 may include a first channel region under the floating gate and a second channel region under the control gate. A contact plug (not shown) may electrically connect the drain region 153 with a bit line on the drain region 153.

FIGS. 18A through 24A and FIGS. 18B through 24B are sectional views taken along lines A-A′ and B-B′ of the example embodiment memory device in FIG. 6, and illustrate an example embodiment method of forming a nonvolatile memory device. Shared features of example embodiments in FIGS. 10A and 10B and example embodiments in FIGS. 18A and 18B through 24A and 24B are omitted from the example embodiment method description below.

As shown in FIGS. 6, 18A, and 18B, a photolithography, etching, and/or other suitable process may be performed to form a first preliminary conductive pattern 131a and a first preliminary insulation pattern 121a on the active region 115 of the semiconductor substrate 110. The gate insulating layer 120 and the first preliminary insulation pattern 121a may be formed of silicon oxide or the like and the first preliminary conductive pattern 131a may be formed of doped polysilicon or the like.

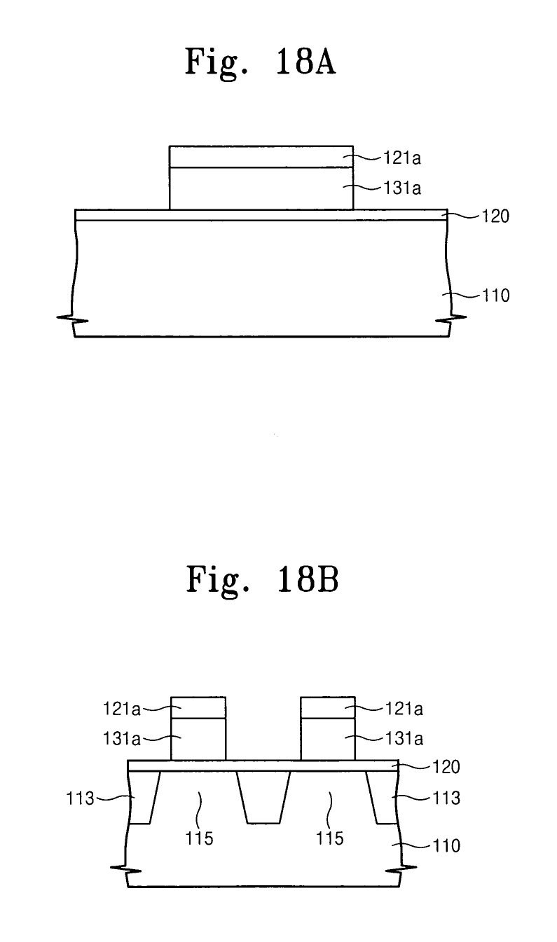

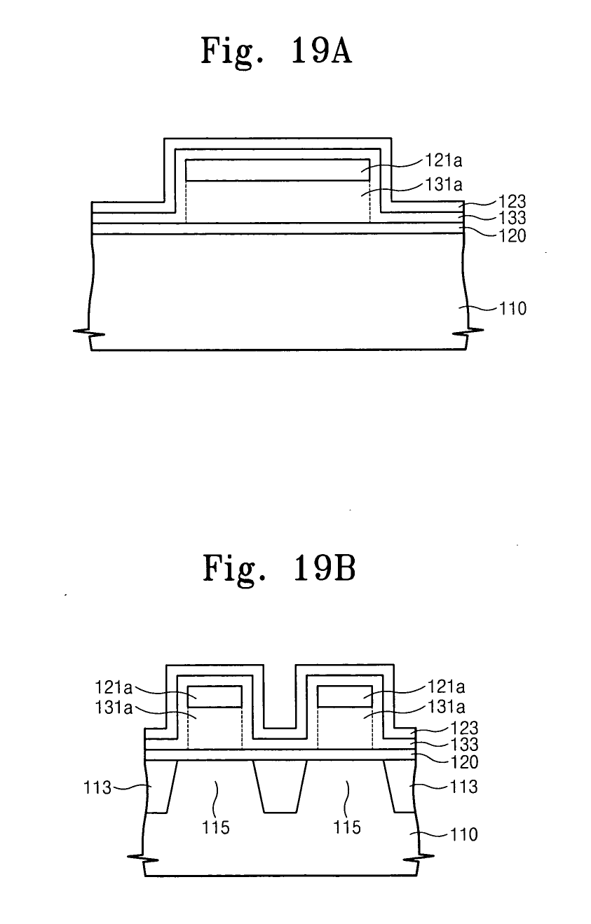

As shown in FIGS. 6, 19A, and 19B, a second conductive layer 133 and a second insulation layer 123 may cover an upper surface of the resultant semiconductor substrate 110. The second conductive layer 133 may be formed of doped polysilicon or the like by a thin film forming process or any suitable method, and the second insulation layer 123 may be formed of silicon nitride or the like by a thin film forming process or another suitable method. An atomic layer deposition (ALD) or similar technique may be used to form the second conductive layer 133 and the second insulation layer 123 on a surface of the first preliminary conductive pattern 131a and the first preliminary insulation pattern 121a. The second conductive layer 133 may cover an upper surface and up to four sidewalls of the first preliminary insulation pattern 121a. The first preliminary insulation pattern 121a may be between the first preliminary conductive pattern 131a and the second conductive layer 133.

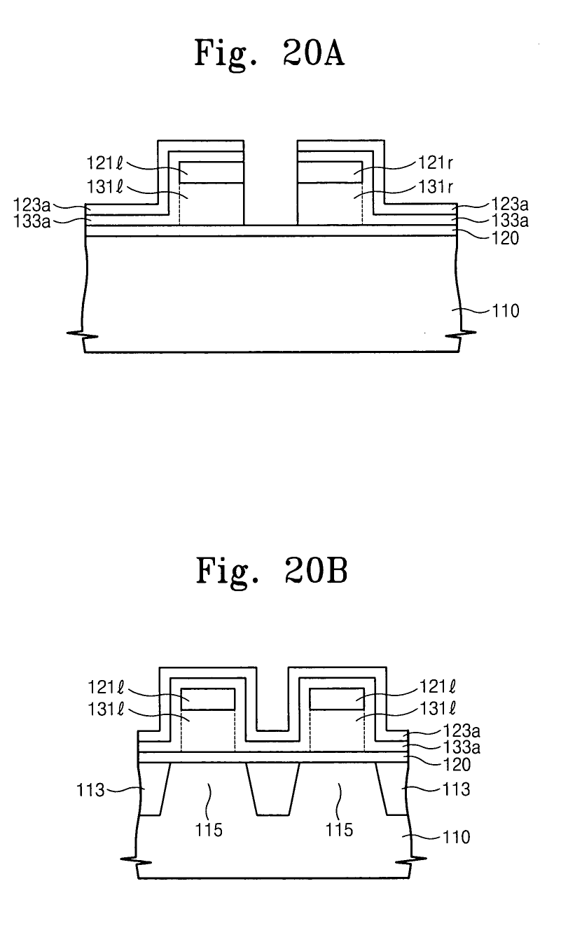

As shown in FIGS. 6, 20A, and 20B, a photolithography, etch, or other suitable process may be performed to form first conductive patterns 131l and 131r and first insulating patterns 121l and 121r. The first two conductive patterns 131l and 131r and the first two insulation patterns 121l and 121r may be formed by removing a middle portion of each of the first preliminary conductive pattern 131a and the first preliminary insulation pattern 121a. The first two conductive patterns 131l and 131r and the first two insulation patterns 121l and 121r may be self-aligned under a second preliminary conductive pattern 133a and a second preliminary insulation pattern 123a extending in a first direction.

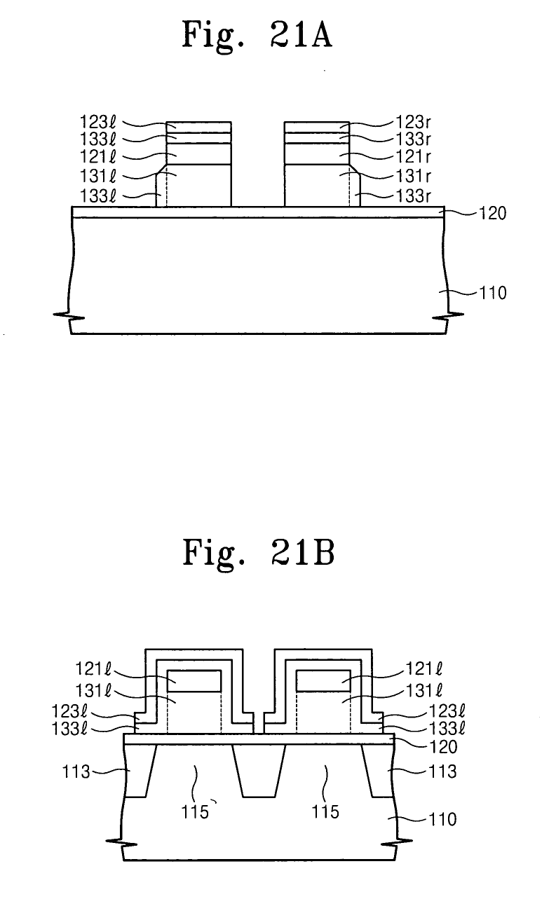

As shown in FIGS. 6, 21A, and 21B, a photolithography, etching, and/or other satiable process may be performed to form second conductive patterns 133l and 133r and second insulating patterns 123l and 123r. The first conductive patterns 131l and 131r may be electrically connected with the second conductive patterns 133l and 133r. The second conductive patterns 133l and 133r and the second insulating patterns 123l and 123r may be arranged in the first direction and second direction, respectively. The second conductive patterns 133l and 133r and the second insulating patterns 123l and 123r may cover up to two sidewalls parallel to the second direction and may expose up to two sidewalls parallel to the first direction. The second conductive patterns 133l and 133r may cover one sidewall parallel to the first direction of the first conductive patterns 133l and 133r.

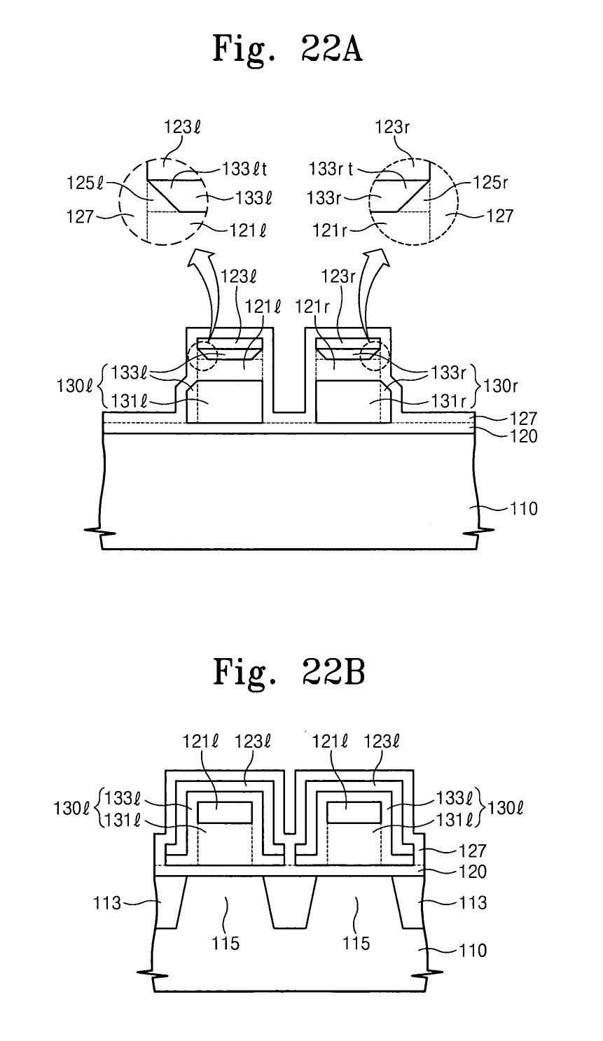

As shown in FIGS. 6, 22A, and 22B, a thermal oxidation process may be performed to form tips 133lt and 133rt at both ends of the second conductive patterns 133l and 133r in the second direction. As shown in circles of FIG. 22A, the tips 133lt and 133rt may be formed while the second conductive patterns 133l and 133r are partially transformed into oxide layers 125l and 125r by a thermal oxidation process. If the first insulating patterns 121l and 121r are silicon oxide or the like and the second insulating patterns 123l and 123r are silicon nitride or the like, the thermal oxidation process may oxidize the polysilicon adjacent to the silicon oxide faster than it oxidizes the polysilicon adjacent to the silicon nitride. The tips 133lt and 133rt may be easily formed using this example embodiment method.

The first conductive patterns 131l and 131r and the second conductive patterns 133l and 133r having the formed tips may form floating gates 130l and 130r. The floating gates 130l and 130r may be arranged in the first direction and the second direction, respectively.

A tunneling insulation layer 127 may be formed on an upper surface of the resultant semiconductor substrate 110. The tunneling insulation layer may be formed of silicon nitride or the like by a thin film forming process or another suitable process.

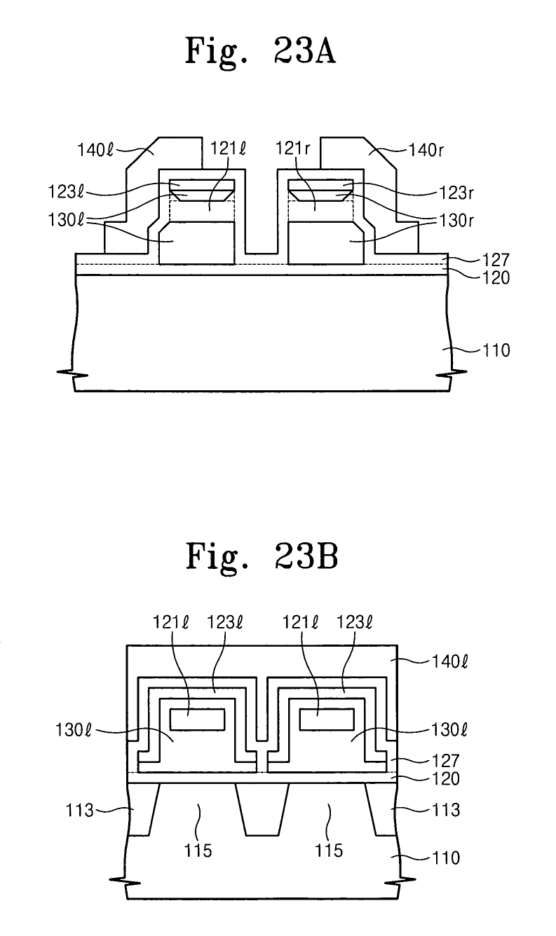

As shown in FIGS. 6, 23A and 23B, a conductive layer may be formed on an upper surface of the resultant semiconductor substrate 110 and may be subject to a photolithography, etching, or other suitable process to form third conductive patterns 140l and 140r extending in the first direction. The third conductive patterns 140l and 140r may be formed of, for example, doped polysilicon or in a stacked structure of a doped polysilicon layer and a silicide layer. The third conductive patterns 140l and 140r may form control gates. The control gates 140l and 140r may be formed at one side of the floating gates 130l and 130r on the active region such that the memory cell may be a split gate type.

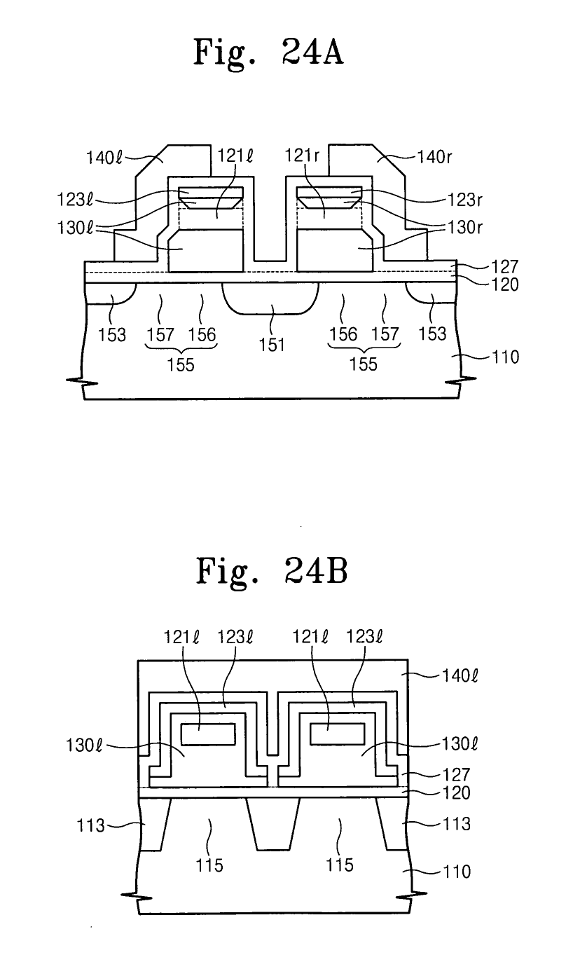

As shown in FIGS. 6, 24A, and 24B, an ion implantation process may be performed to form a source line 151 extending in the first direction in the active region 115 between the floating gates 130r and 130l and to form a drain region 153 in the active region 115 outside the control gates 140l and 140r. By doing so, a channel region 155 may be defined between the source line 151 and the drain region 153. The channel region 155 may include a first channel region 156 under the floating gate and a second channel region 157 under the control gate. A contact plug (not shown) may electrically connect the drain region 153 with a bit line can be formed on the drain region 153.

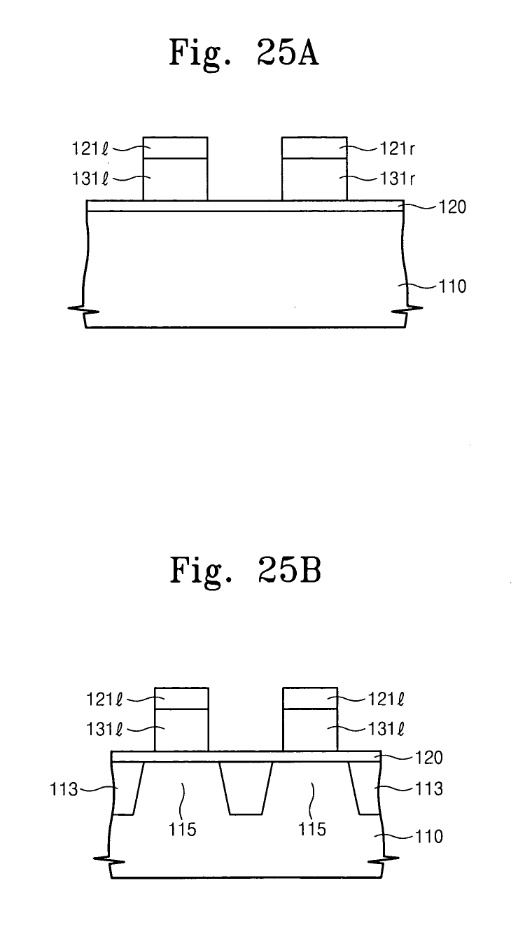

FIGS. 25A through 30A and FIGS. 25B through 30B are sectional views taken along lines A-A′ and B-B′ of the example embodiment memory device of FIG. 8 and illustrate an example method of forming a nonvolatile memory device. Shared features of example embodiments in FIGS. 10A and 10B and example embodiments in FIGS. 25A and 25B through 30A and 30B are omitted from the example embodiment method description below.

As shown in FIGS. 8, 25A and 25B, a photolithography, etching, or other suitable process may be performed to form first conductive pattern 133l and 133r and first insulating patterns 121l and 121r on the active region 115 of the semiconductor substrate 110. The gate insulating layer 120 and the first insulating patterns 121l and 121r may be formed of silicon oxide or the like and the first conductive patterns 131l and 131r may be formed of doped polysilicon or the like.

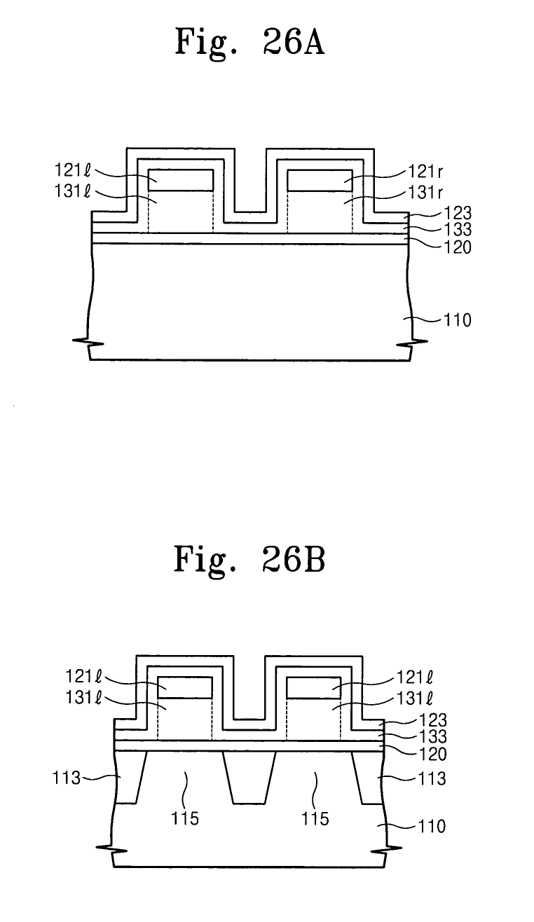

As shown in FIGS. 8, 26A, and 26B, a second conductive layer 133 and a second insulation layer 123 may cover an upper surface of the semiconductor substrate 110. The second conductive layer 133 may be formed of doped polysilicon or the like by a thin film forming process or another suitable process, and the second insulation layer 123 can be formed of silicon nitride or the like by a thin film forming process or another suitable process. An atomic layer deposition (ALD) technique or another suitable method may be used to form the second conductive layer 133 and the second insulation layer 123 along profiles of the first conductive patterns 131l and 131r and the first insulating patterns 121l and 121r. The second conductive layer 133 may cover an upper surface and up to four sidewalls of the first insulating patterns 121l and 121r. The first insulating patterns 121l and 121r may be between the first conductive patterns 131l and 131r and the second conductive layer 133.

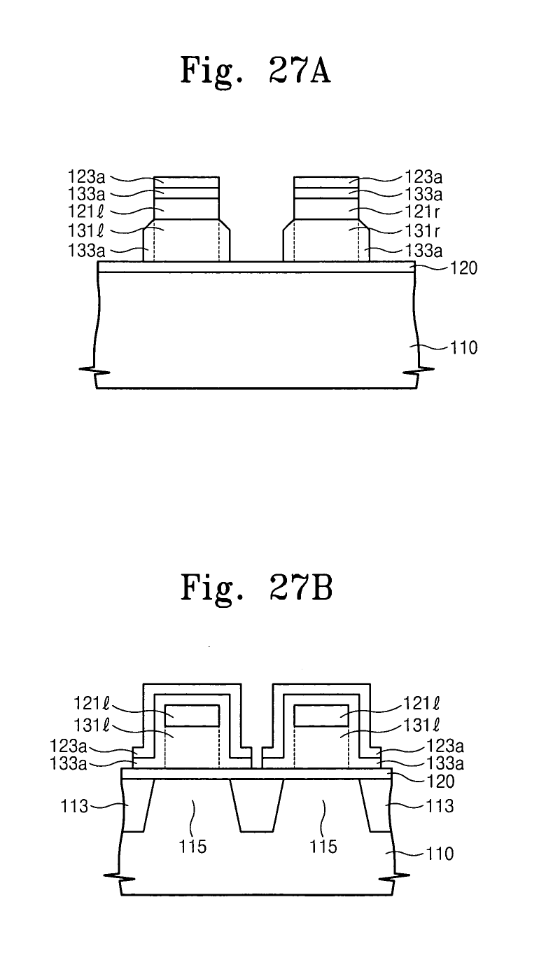

As shown in FIGS. 8, 27A and 27B, a photolithography, etching, and/or other suitable process may be performed to form a second preliminary conductive pattern 133a and a second preliminary insulation pattern 123a arranged in the first direction and the second direction, respectively. The second preliminary conductive pattern 133a and the second preliminary insulation pattern 123a may cover up to two sidewalls parallel the first insulating patterns 121l and 121r and may expose up to two sidewalls parallel in the first direction. The second preliminary conductive pattern 133a may cover one sidewall of the first conductive patterns 131l and 131r parallel in the first direction. The second preliminary conductive pattern 133a may cover two sidewalls and face in the first direction of the first insulating patterns 121l and 121r parallel in the second direction, and the second preliminary conductive patterns 131l and 131r may also cover two sidewalls and face in the second direction. The second preliminary conductive pattern 133a may also cover all of the sidewalls of the first insulating patterns 121l and 121r. The second preliminary conductive pattern 133a and the second preliminary insulation pattern 123a may be formed in any structure and shape to achieve a desired device integration, erase efficiency, and/or other similar characteristic.

The first conductive patterns 131l and 131r may be electrically connected with the second preliminary conductive pattern 133a, and the second preliminary conductive pattern 133a and the second preliminary insulation pattern 123a may be arranged in the first and second directions, respectively.

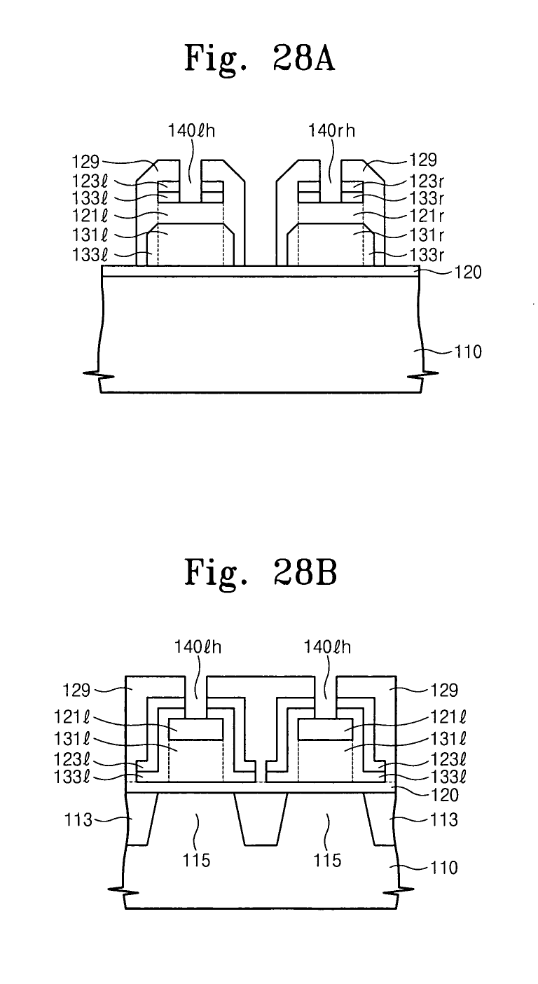

As shown in FIGS. 8, 28A, and 28B, a photolithography, etching, and/or any suitable process may be performed to form second conductive patterns 133l and 133r and second insulating patterns 123l and 123r. An oxide pattern 129 may be formed before the second conductive patterns 133l and 133r and the second insulating patterns 123l and 123r. The oxide pattern 129 may be used as an etch mask while the second insulating patterns 123l and 123r and the second conductive patterns 133l and 133r are formed. The first and second conductive patterns 131l, 132r, 133l, and 133r and the first and second insulating patterns 121l, 121r, 123l, and 123r may be surrounded by the oxide pattern 129. Some sidewalls of the second insulating patterns 123l and 123r and of the second conductive patterns 133l and 133r and the upper surfaces of the first insulating patterns 121l and 121r may be partially exposed. Openings 140lh and 140rh may partially expose the upper surfaces of the first insulating patterns 121l and 121r due to the configuration of the second conducive patterns 133l and 133r, the second insulating patterns 123l and 123r, and the oxide pattern 129. The openings 140lh and 140rh may be optionally shaped to expose a middle portion of each of the upper surfaces of the first insulating patterns 121l and 121r. The openings 140lh and 140rh may also be shaped so that they do not expose the second conductive patterns 133l and 133r between the first insulating patterns 121l and 121r and the second insulating patterns 123l and 123r.

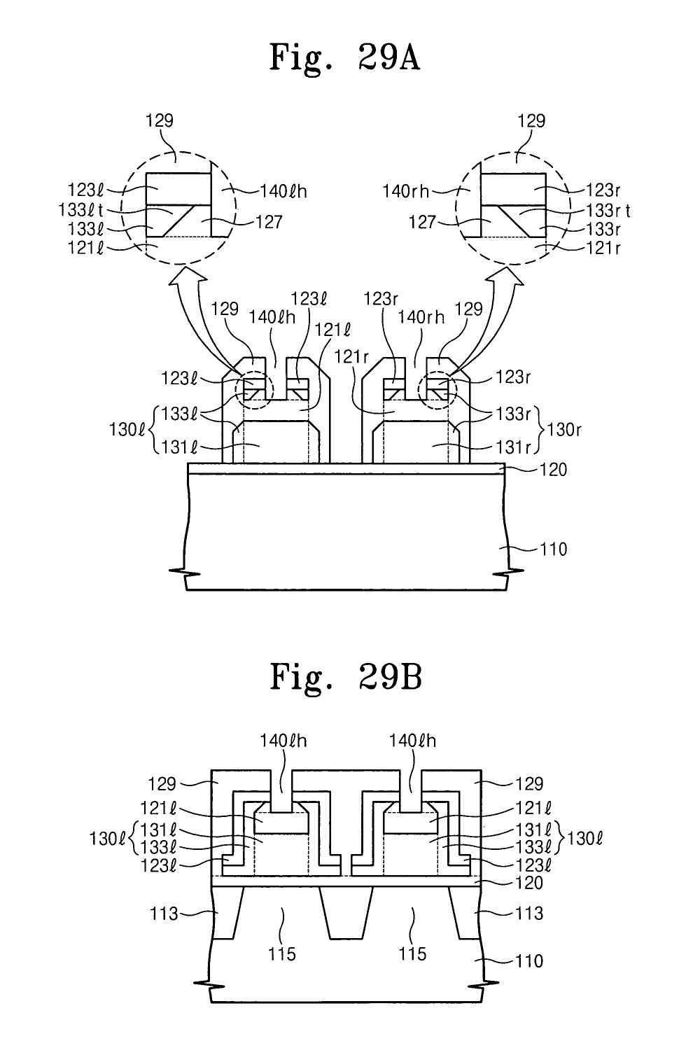

As shown in FIGS. 8, 29A, and 29B, a thermal oxidation process may be performed to form tips 133lt and 133rt in the second conductive patterns 133l and 133r. As shown in circles of FIG. 22A, the tips 133lt and 133rt may be formed while the second conductive patterns 133l and 133r, which may be exposed by the openings 140l and 140r, may be partially transformed into an oxide layer 127 by a thermal oxidation process. If the first insulating patterns 121l and 121r are silicon oxide or the like and the second insulating patterns 123l and 123r are silicon nitride or the like, the thermal oxidation process oxidizes the polysilicon adjacent to the silicon oxide faster than it oxidizes the polysilicon adjacent to the silicon nitride. The tips 133lt and 133rt may be easily formed by using this example embodiment method. The oxide layer 127 formed by the thermal oxidation process may be a tunneling oxide layer. A separate tunneling oxide layer may also be formed.

The first conductive patterns 131l and 131r and the second conductive patterns 133l and 133r having the formed tips may act as floating gates 130l and 130r. The floating gates 130l and 130r may be arranged in the first direction and the second direction, respectively.

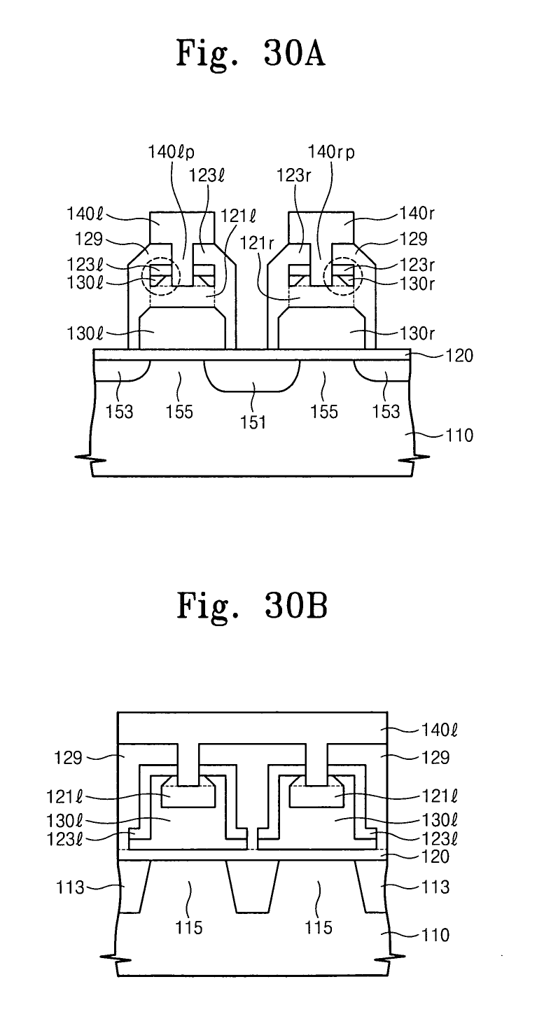

As shown in FIGS. 8, 30A, and 30B, a conductive layer may be formed on an upper surface of the semiconductor substrate 110, and may be subject to a photolithography, etching, and/or another suitable process to form third conductive patterns 140l and 140r extending in the first direction. The third conductive patterns 140l and 140r may have conductive plugs 140lp and 140rp protruding downward and contacting the first insulating patterns. The conductive plugs 140lp and 140rp may be formed by filling the conductive layer in the openings 140lh and 140rh. The third conductive patterns 140l and 140r may be formed of, for example, doped polysilicon or a stacked structure of a doped polysilicon layer and/or a silicide layer. The second conductive patterns 133l and 133r may optionally surround the conductive plugs 140lp and 140rp. The second conductive patterns 133l and 133r may be shaped in any configuration that allows F-N tunneling current to flow between the tips 133lt and 133rt of the floating gate and the conductive plugs 140lp and 140rp.

An ion implantation process may be performed to form a source line 151 and a drain region 153. Also, a channel region 155 may be defined in the active region between the source line 151 and the drain region 153.

Tips may be formed in the floating gate regardless of the memory cell type, which may enhance the cell's erase efficiency.

Tips may be formed in the floating gate without using a LOCOS technique, which may reduce or prevent irregularity of the tips, lowering reliability of the memory device due to irregularity of the tips, and/or limiting integration that may be caused by using the LOCOS technique.

The example embodiment memory device may be more highly integrated and/or the tips may be more stably formed.

While the example embodiments have been particularly shown and described with reference to drawings, it will be understood by those of ordinary skill in the art that various changes in form and details may be made therein without departing from the scope of the following claims.

What is claimed is:

1. A floating gate structure comprising:
a first floating gate;
a second floating gate on the first floating gate, wherein the second floating gate has a tip formed at a longitudinal end thereof;
a first insulating pattern between the first floating gate and the second floating gate; and
a gate connecting layer formed on at least one sidewall of the first insulating pattern and not contacting the tip of the second floating gate.

2. The floating gate structure of claim 1, wherein the gate connecting layer electrically connects the first floating gate and the second floating gate.

3. A nonvolatile memory device comprising:
the floating gate structure of claim 2 on a semiconductor substrate;
a gate insulating layer between the floating gate structure and the semiconductor substrate;
a control gate adjacent to the floating gate structure; and
a tunneling insulation layer between the control gate and the floating gate structure.

4. The floating gate structure of claim 1, wherein the first floating gate, the second floating gate, and the gate connecting layer are formed of the same material.

5. The floating gate structure of claim 1, further comprising:
a second insulating pattern formed on the second floating gate, wherein the first insulating pattern is formed of silicon oxide and the second insulating pattern is formed of silicon nitride.

6. The nonvolatile memory device of claim 3, wherein the control gate is on the gate insulating layer at one side of the floating gate structure, a source line is in the semiconductor substrate at the other side of the floating gate structure, and a drain region is in the semiconductor substrate in a region opposite the floating gate structure, and the control gate is between the source line and the drain region.

7. The nonvolatile memory device of claim 3, wherein the control gate is on the floating gate structure, the second floating gate structure has an opening that exposes the first insulating pattern, and the tip is formed at a longitudinal end of the opening.

8. The nonvolatile memory device of claim 7, wherein the control gate has a lower portion extending into the opening and contacting the first insulating pattern.

9. The nonvolatile memory device of claim 7, wherein the gate insulating layer is formed on four sidewalls of the first insulating pattern.

10. A method of forming a nonvolatile memory device, the method comprising:
forming a gate insulating layer on a semiconductor substrate;
forming a floating gate structure on the gate insulating layer, wherein the floating structure includes a first conductive pattern, a first insulating layer, and a second conductive pattern sequentially stacked on the gate insulating layer;
forming a tip at a longitudinal end of the second conductive pattern; and
forming a control gate at a position adjacent to the tip.

11. The method of claim 10, wherein the second conductive pattern extends downward from at least one sidewall of the floating gate structure and is electrically connected with the first conductive pattern.

12. The method of claim 11, further comprising:
forming a second insulating pattern on the second conductive pattern, wherein the tip is formed at the longitudinal end of the second conductive pattern exposed between the first insulating pattern and the second insulating pattern.

13. The method of claim 12, wherein forming the floating gate structure includes forming and patterning a first conductive layer and a first insulating layer on the gate insulating layer to form a first preliminary conductive pattern and a first preliminary insulating pattern, forming a second conductive layer and a second insulating layer on the semiconductor substrate, and patterning the second insulating layer, the second conductive layer, the first preliminary insulating pattern, and the first preliminary conductive pattern to form the second insulating pattern, the second conductive pattern, the first insulating pattern and the first conductive pattern.

14. The method of claim 13, wherein the first insulating pattern and the first conductive pattern are formed by removing a middle portion of each of the first preliminary insulating pattern and the first preliminary conductive pattern to divide each of the first preliminary insulating pattern and the first preliminary conductive pattern into two portions, and the second conductive pattern has a longitudinal end exposed between the first insulating pattern and the second insulating pattern on at least one sidewall of the second conductive pattern.

15. The method of claim 12, wherein the first insulating layer is formed of silicon oxide and the second insulating layer is formed of silicon nitride.

16. The method of claim 10, wherein the tip is formed by performing a thermal oxidation process of the longitudinal end of the second conductive pattern.

17. The method of claim 10, further comprising:.
forming a tunneling insulation layer on the semiconductor substrate prior to forming the control gate.

18. The method of claim 10, wherein forming the floating gate structure comprises:
forming and patterning a first conductive layer and a first insulating layer on the gate insulating layer to form the first conductive pattern and the first insulating pattern;
forming a second conductive layer and a second insulating layer on the semiconductor substrate;
patterning the second insulating layer and the second conductive layer to form a second preliminary insulating pattern and a second preliminary conductive pattern covering the first conductive pattern and the first insulating pattern; and
patterning the second preliminary insulating pattern and the second preliminary conductive pattern to form the second insulating pattern and the second conductive pattern partially exposing the upper surface of the first insulating pattern, wherein a sidewall of the second conductive pattern is exposed between the first insulating pattern and the second insulating pattern.

19. The method of claim 18, wherein the first insulating layer is formed of silicon oxide and the second insulating layer is formed of silicon nitride.

20. The method of claim 11, wherein the tip is formed by performing a thermal oxidation process of the at least one sidewall of the second conductive pattern exposed between the first insulating pattern and the second insulating pattern.

21. The method of claim 10, further comprising: forming a tunneling insulation layer interposed between the tip and the control gate prior to forming the control gate

22. The method of claim 21, wherein the tunneling insulation layer is formed by thermally oxidizing the second conductive pattern while the tip is formed.
